(19) United States
(12) Patent Application Publication
(10) Pub. No.: US 2026/0164645 A1
(43) Pub. Date: Jun. 11, 2026

(54) SEMICONDUCTOR STRUCTURE INCLUDING A CAPACITOR STRUCTURE AND METHOD OF MANUFACTURING THE SAME

(71) Applicant: NANYA TECHNOLOGY CORPORATION, NEW TAIPEI CITY (TW)

(72) Inventor: YING-CHENG CHUANG, NEW TAIPEI CITY (TW)

(21) Appl. No.: 18/989,122

(22) Filed: Dec. 20, 2024

Related U.S. Application Data
(63) Continuation of application No. 18/971,102, filed on Dec. 6, 2024.

(51) Int. Cl. H10B 12/00

(52) U.S. Cl. CPC H10B 12/488; H10B 12/37; H10B 12/50

(57) ABSTRACT

A semiconductor structure and a method of manufacturing the same are provided. The semiconductor structure includes a base structure, a patterned circuit structure, a capacitor structure and a vertical transistor. The patterned circuit structure is disposed over the base structure. The capacitor structure is disposed over the patterned circuit structure. The vertical transistor is disposed over the capacitor structure.

### CROSS-REFERENCE TO RELATED APPLICATION

This application is a continuation application of U.S. Non-Provisional application Ser. No. 18/971,102 filed Dec. 6, 2024, which is incorporated herein by reference in its entirety.

### TECHNICAL FIELD

The present disclosure relates to a semiconductor structure and a method of manufacturing the same, and more particularly, to a semiconductor structure including capacitor structure, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include signal lines, such as word lines and bit lines crossing the word lines. As DRAM devices are scaled down and the dimensions and/or pitches of the signal lines are getting smaller, the space utilization will be a critical concern.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor structure. The semiconductor structure includes a base structure, a patterned circuit structure, a capacitor structure and a vertical transistor. The patterned circuit structure is disposed over the base structure. The capacitor structure is disposed over the patterned circuit structure. The vertical transistor is disposed over the capacitor structure.

Another aspect of the present disclosure provides a semiconductor structure. The semiconductor structure includes a base structure, a patterned circuit structure, an intermediate structure, a capacitor structure, an upper structure and a vertical transistor. The patterned circuit structure is disposed over the base structure, and includes a metal-oxide-semiconductor (MOS) structure. The intermediate structure is disposed over the patterned circuit structure. The capacitor structure is embedded in the intermediate structure and is disposed over the patterned circuit structure. The upper structure is disposed on the intermediate structure. The vertical transistor is embedded in the upper structure.

Another aspect of the present disclosure provides a method of manufacturing a semiconductor structure. The method includes: forming a patterned circuit structure on a base structure; forming a capacitor structure over the patterned circuit structure; and forming a vertical transistor over the capacitor structure.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

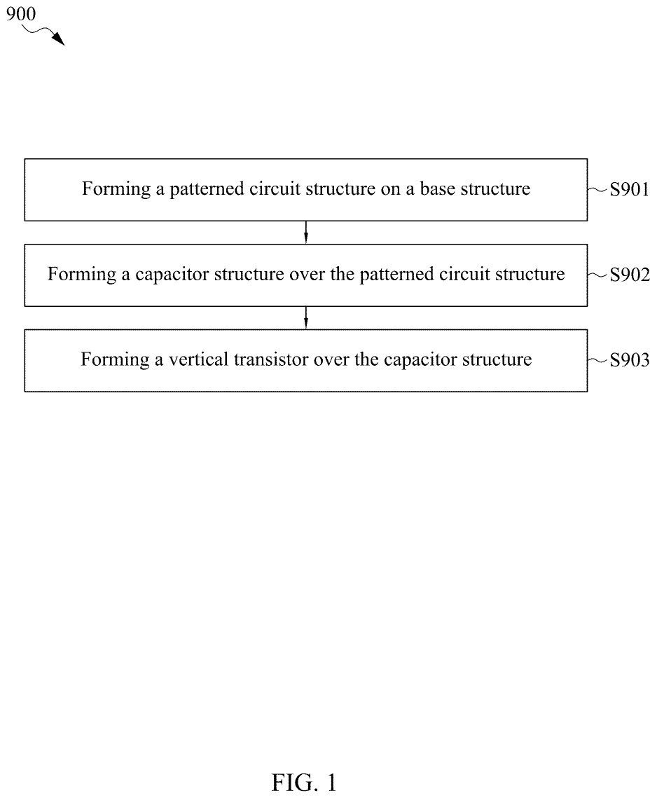

FIG. 1 illustrates, in a flowchart diagram form, a method of manufacturing a semiconductor structure in accordance with one embodiment of the present disclosure.

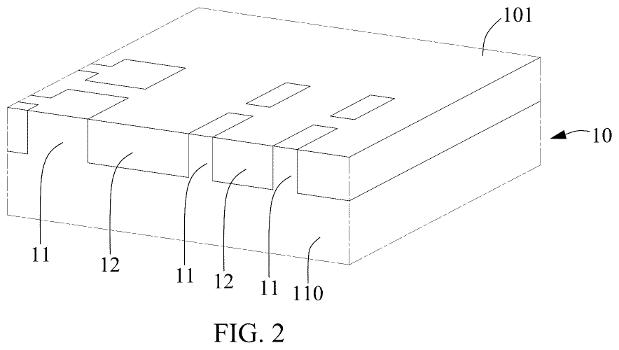

FIG. 2 illustrates a perspective view of one or more stages of an example of a method of manufacturing a semiconductor structure in accordance with one embodiment of the present disclosure.

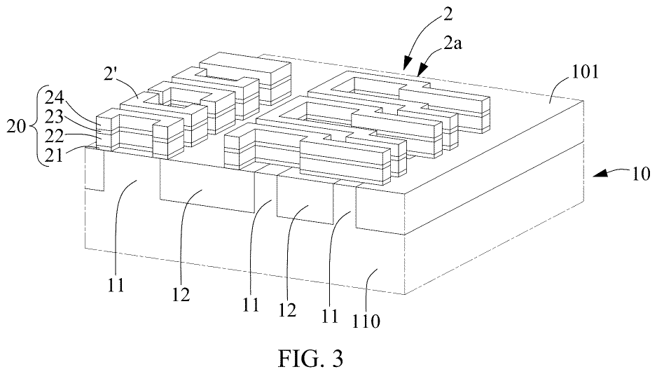

FIG. 3 illustrates a perspective view of one or more stages of an example of a method of manufacturing a semiconductor structure in accordance with one embodiment of the present disclosure.

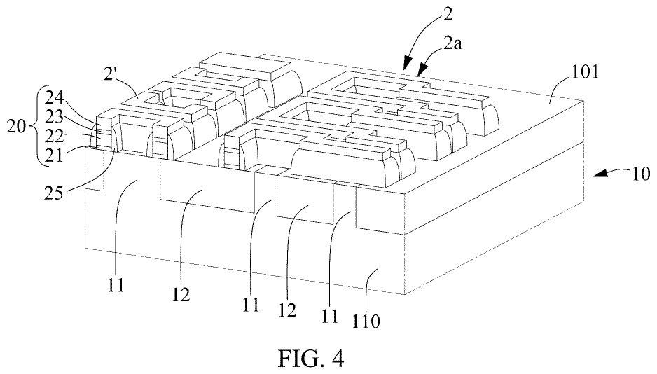

FIG. 4 illustrates a perspective view of one or more stages of an example of a method of manufacturing a semiconductor structure in accordance with one embodiment of the present disclosure.

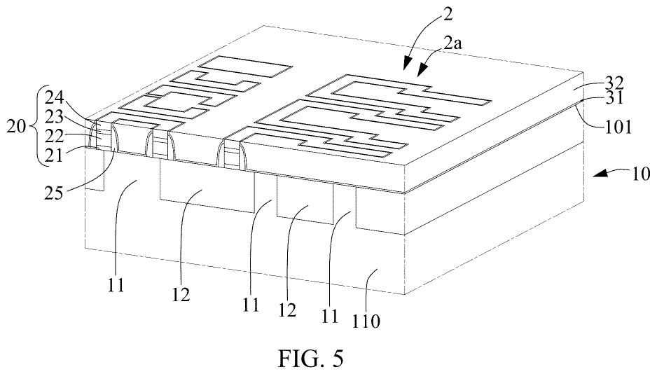

FIG. 5 illustrates a perspective view of one or more stages of an example of a method of manufacturing a semiconductor structure in accordance with one embodiment of the present disclosure.

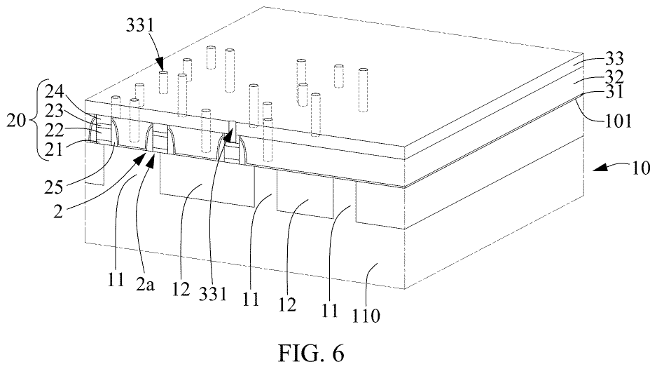

FIG. 6 illustrates a perspective view of one or more stages of an example of a method of manufacturing a semiconductor structure in accordance with one embodiment of the present disclosure.

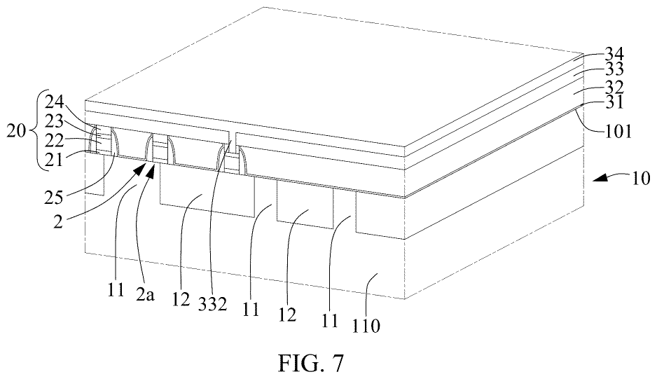

FIG. 7 illustrates a perspective view of one or more stages of an example of a method of manufacturing a semiconductor structure in accordance with one embodiment of the present disclosure.

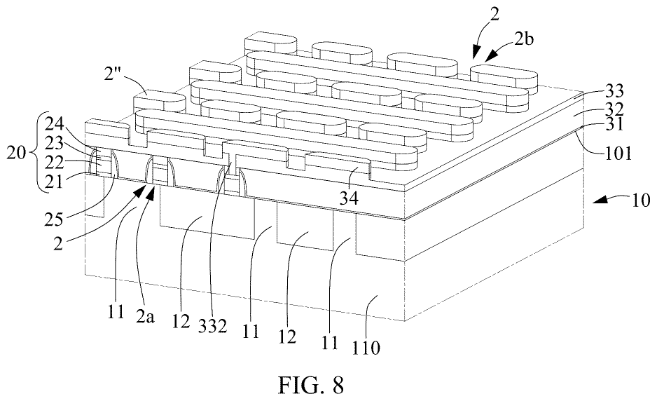

FIG. 8 illustrates a perspective view of one or more stages of an example of a method of manufacturing a semiconductor structure in accordance with one embodiment of the present disclosure.

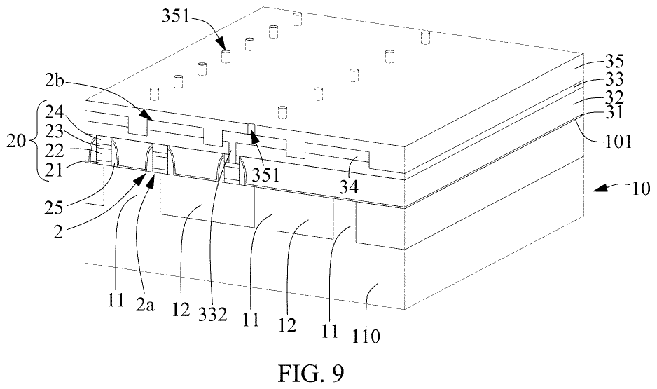

FIG. 9 illustrates a perspective view of one or more stages of an example of a method of manufacturing a semiconductor structure in accordance with one embodiment of the present disclosure.

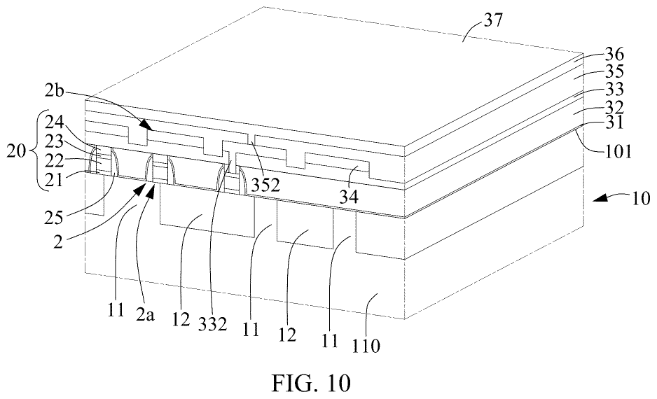

FIG. 10 illustrates a perspective view of one or more stages of an example of a method of manufacturing a semiconductor structure in accordance with one embodiment of the present disclosure.

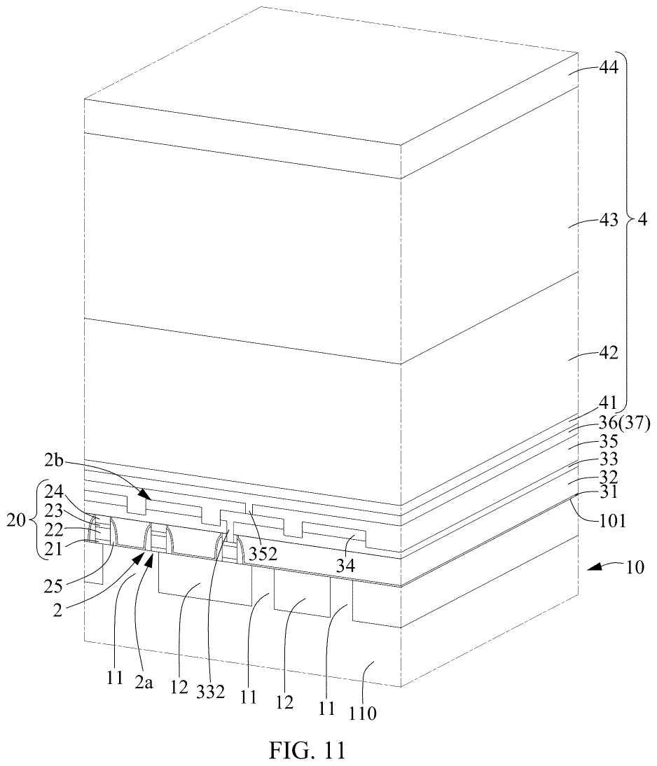

FIG. 11 illustrates a perspective view of one or more stages of an example of a method of manufacturing a semiconductor structure in accordance with one embodiment of the present disclosure.

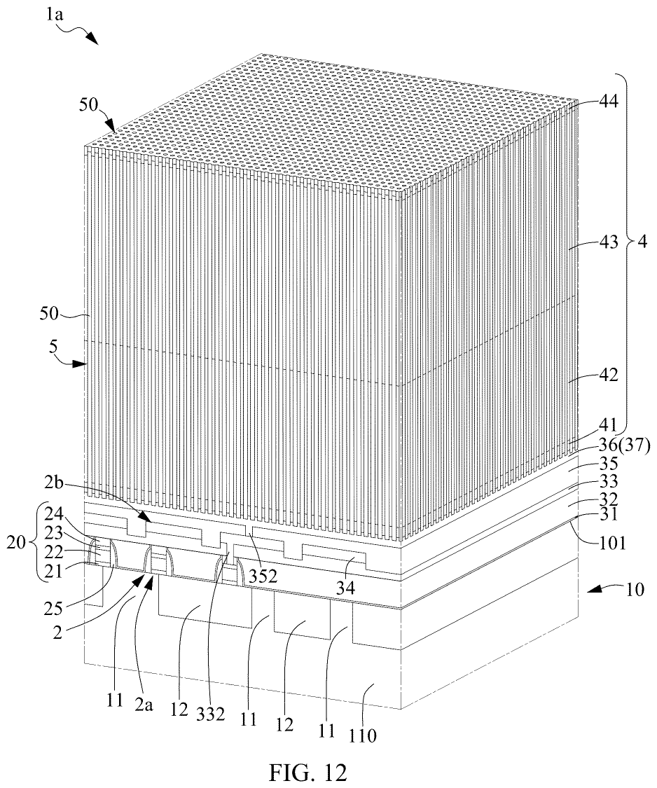

FIG. 12 illustrates a perspective view of one or more stages of an example of a method of manufacturing a semiconductor structure in accordance with one embodiment of the present disclosure.

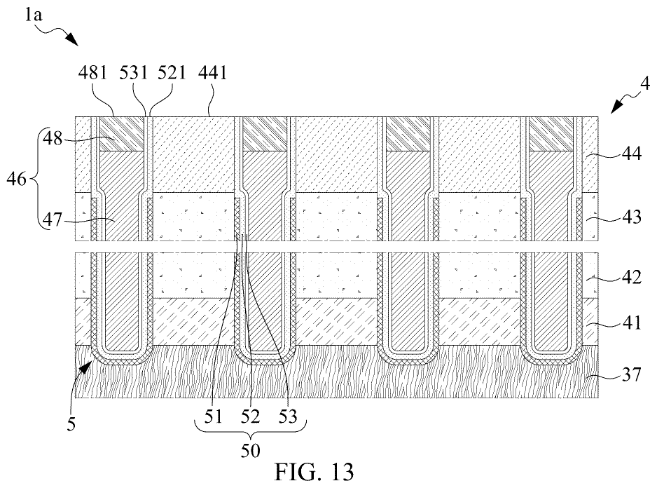

FIG. 13 illustrates a partially enlarged left side view FIG. 12.

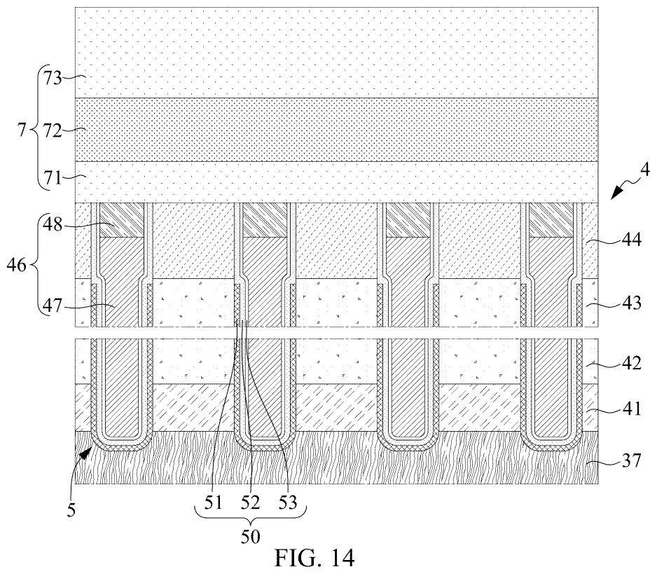

FIG. 14 illustrates a partially enlarged cross-sectional view of one or more stages of an example of a method of manufacturing a semiconductor structure in accordance with one embodiment of the present disclosure.

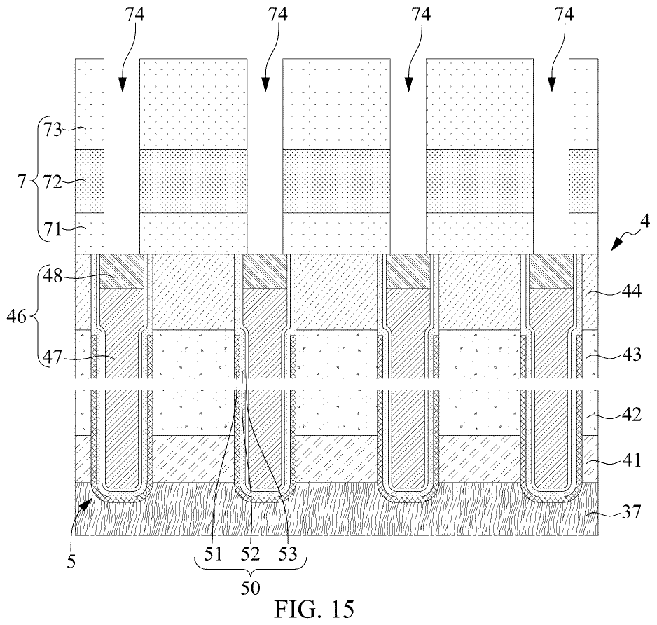

FIG. 15 illustrates a partially enlarged cross-sectional view of one or more stages of an example of a method of manufacturing a semiconductor structure in accordance with one embodiment of the present disclosure.

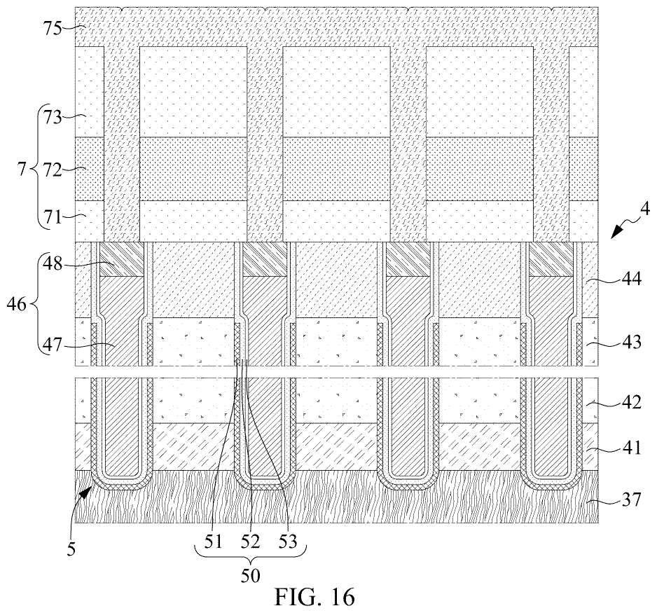

FIG. 16 illustrates a partially enlarged cross-sectional view of one or more stages of an example of a method of manufacturing a semiconductor structure in accordance with one embodiment of the present disclosure.

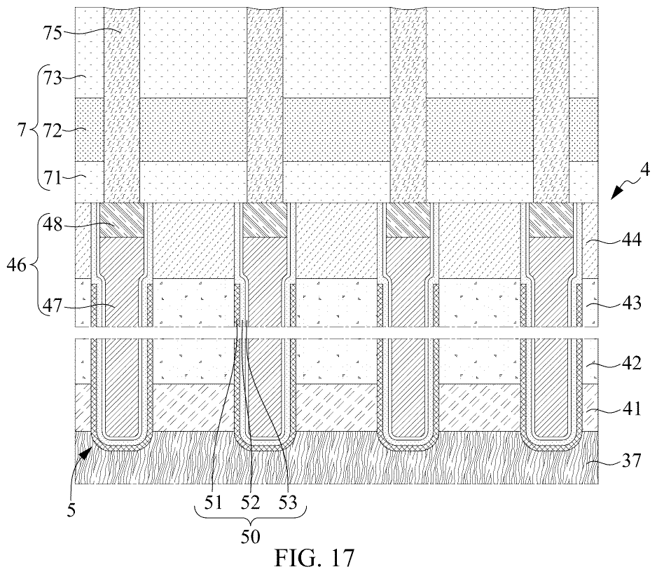

FIG. 17 illustrates a partially enlarged cross-sectional view of one or more stages of an example of a method of manufacturing a semiconductor structure in accordance with one embodiment of the present disclosure.

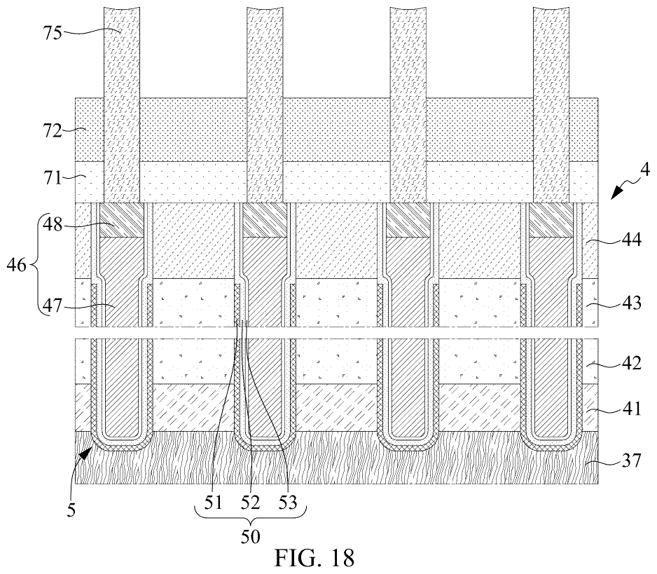

FIG. 18 illustrates a partially enlarged cross-sectional view of one or more stages of an example of a method of manufacturing a semiconductor structure in accordance with one embodiment of the present disclosure.

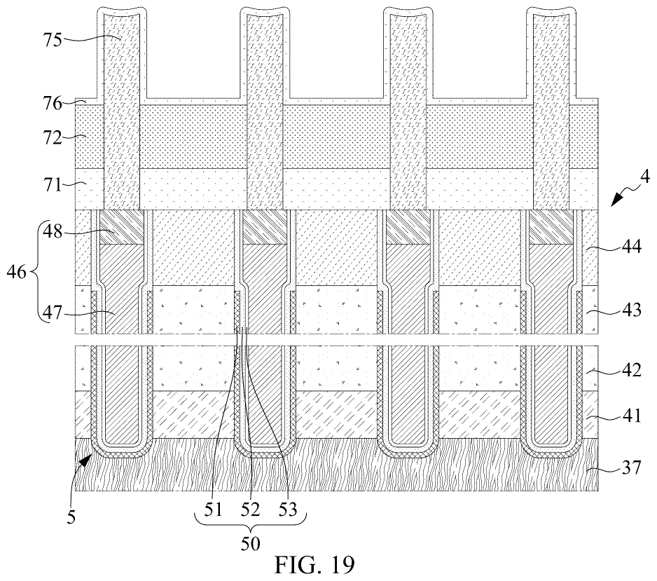

FIG. 19 illustrates a partially enlarged cross-sectional view of one or more stages of an example of a method of manufacturing a semiconductor structure in accordance with one embodiment of the present disclosure.

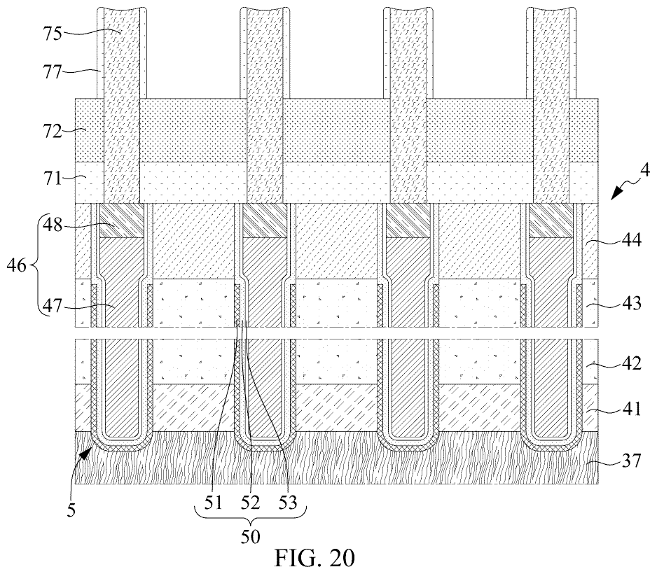

FIG. 20 illustrates a partially enlarged cross-sectional view of one or more stages of an example of a method of manufacturing a semiconductor structure in accordance with one embodiment of the present disclosure.

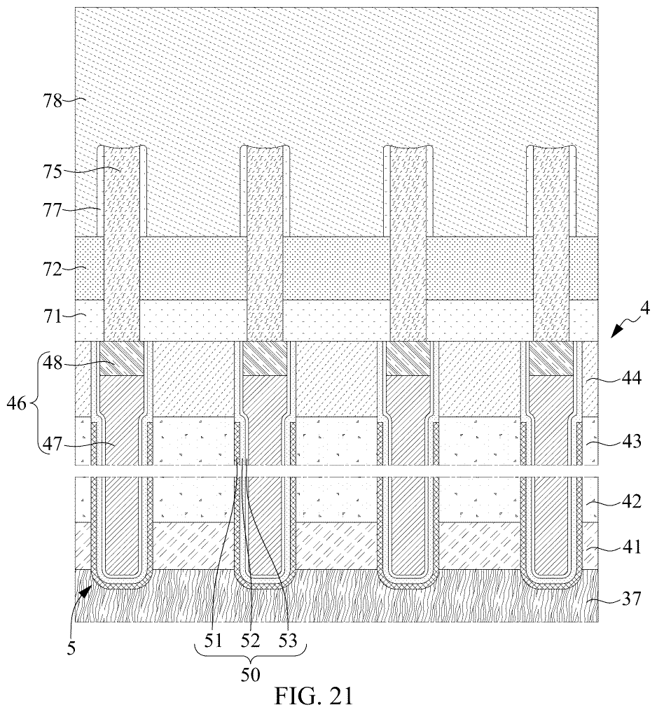

FIG. 21 illustrates a partially enlarged cross-sectional view of one or more stages of an example of a method of manufacturing a semiconductor structure in accordance with one embodiment of the present disclosure.

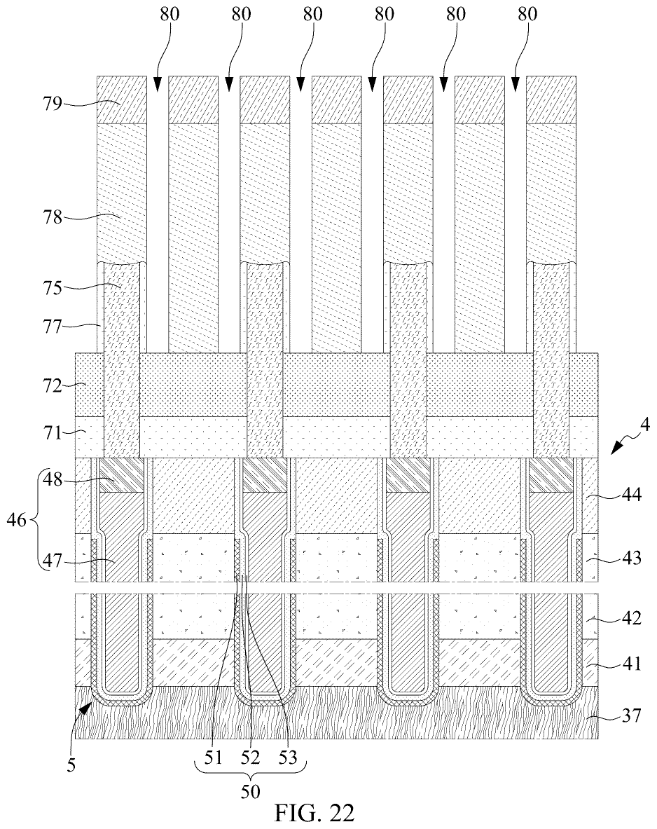

FIG. 22 illustrates a partially enlarged cross-sectional view of one or more stages of an example of a method of manufacturing a semiconductor structure in accordance with one embodiment of the present disclosure.

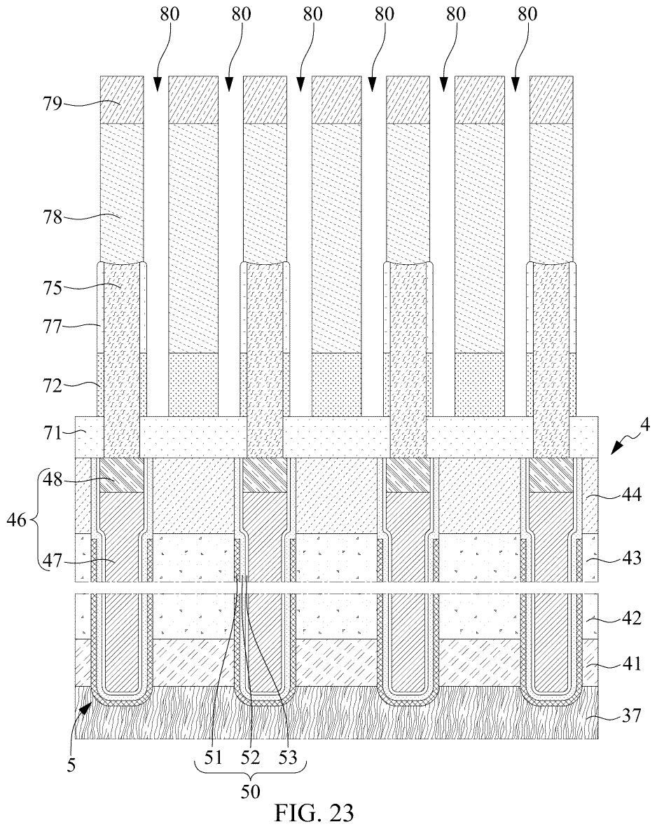

FIG. 23 illustrates a partially enlarged cross-sectional view of one or more stages of an example of a method of manufacturing a semiconductor structure in accordance with one embodiment of the present disclosure.

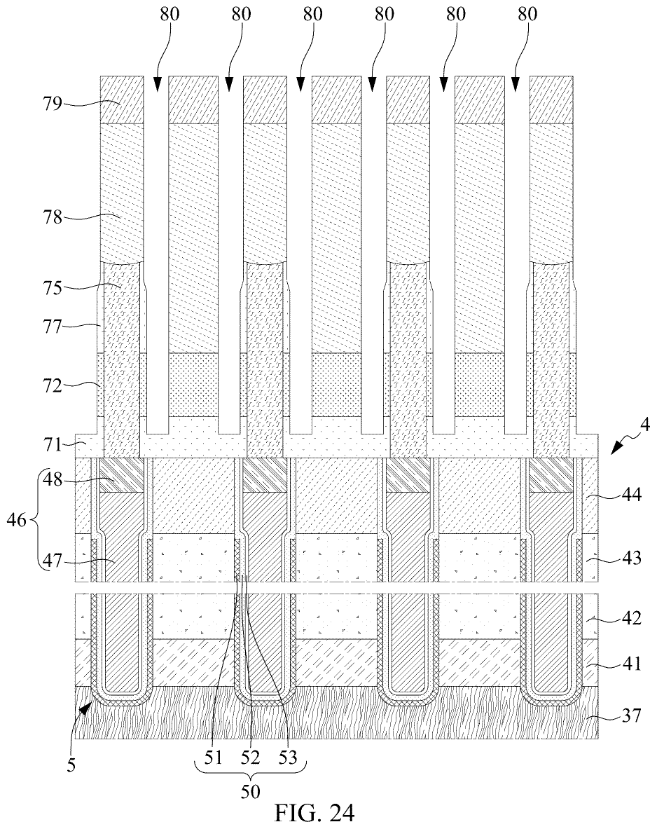

FIG. 24 illustrates a partially enlarged cross-sectional view of one or more stages of an example of a method of manufacturing a semiconductor structure in accordance with one embodiment of the present disclosure.

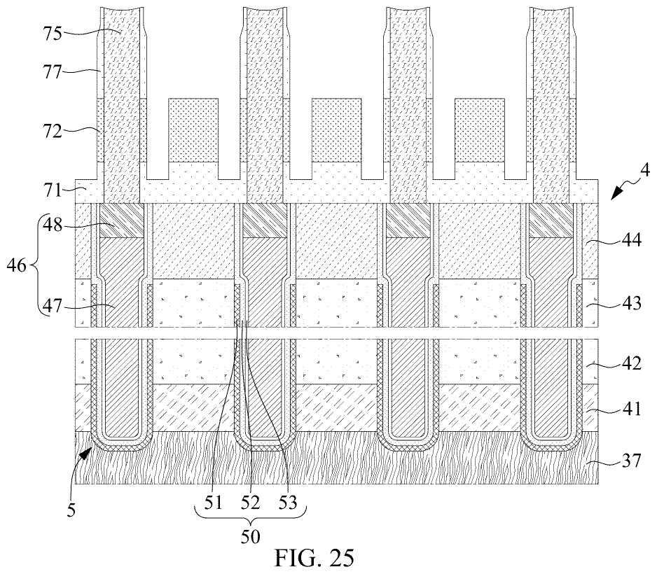

FIG. 25 illustrates a partially enlarged cross-sectional view of one or more stages of an example of a method of manufacturing a semiconductor structure in accordance with one embodiment of the present disclosure.

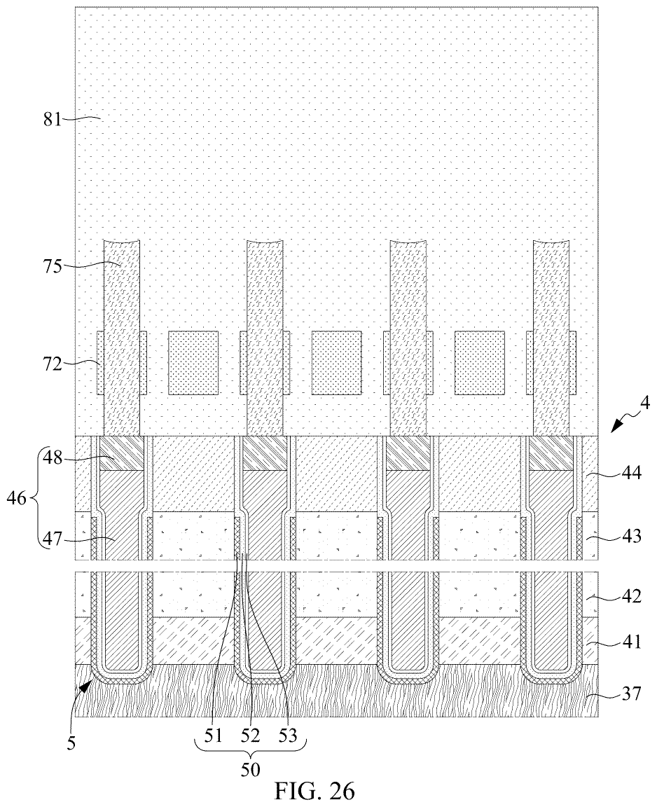

FIG. 26 illustrates a partially enlarged cross-sectional view of one or more stages of an example of a method of manufacturing a semiconductor structure in accordance with one embodiment of the present disclosure.

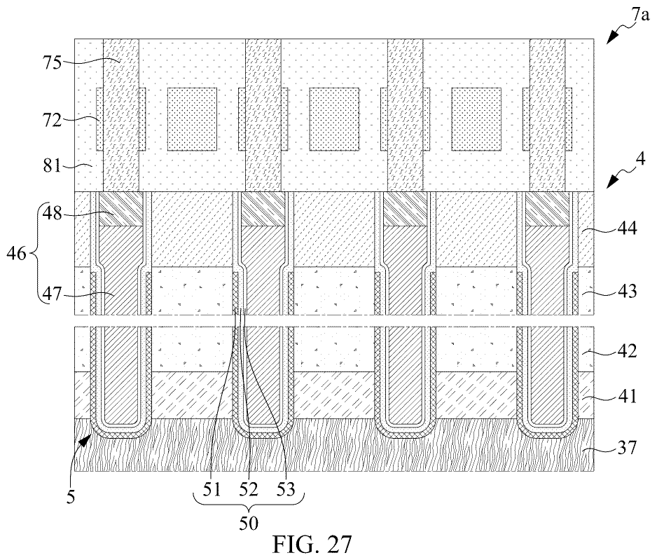

FIG. 27 illustrates a partially enlarged cross-sectional view of one or more stages of an example of a method of manufacturing a semiconductor structure in accordance with one embodiment of the present disclosure.

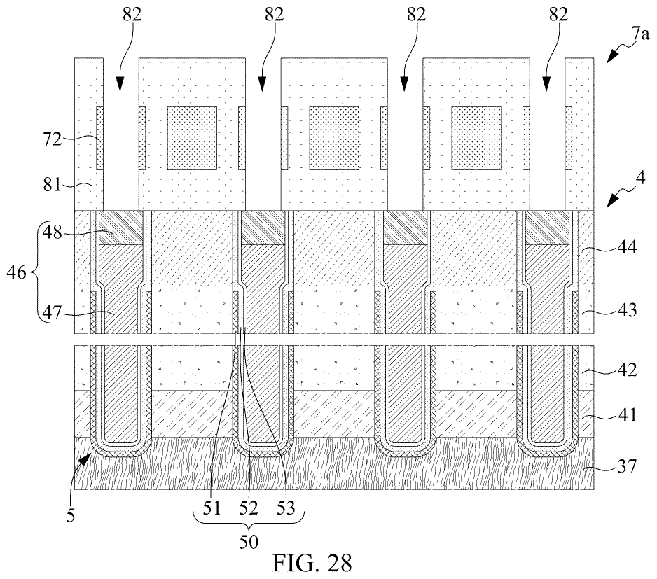

FIG. 28 illustrates a partially enlarged cross-sectional view of one or more stages of an example of a method of manufacturing a semiconductor structure in accordance with one embodiment of the present disclosure.

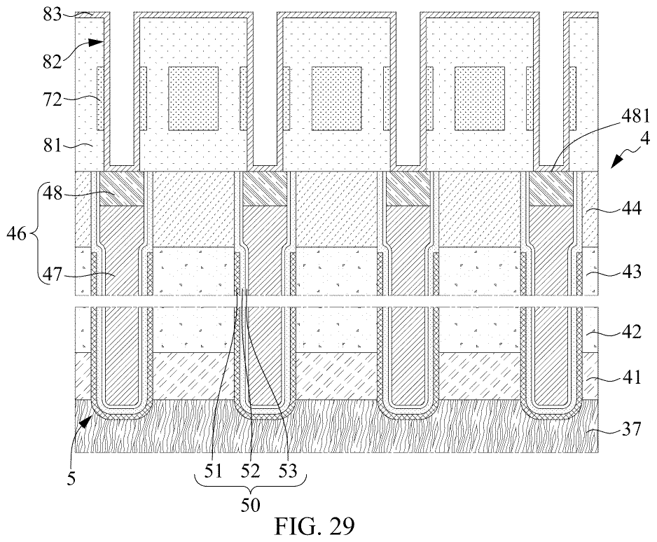

FIG. 29 illustrates a partially enlarged cross-sectional view of one or more stages of an example of a method of manufacturing a semiconductor structure in accordance with one embodiment of the present disclosure.

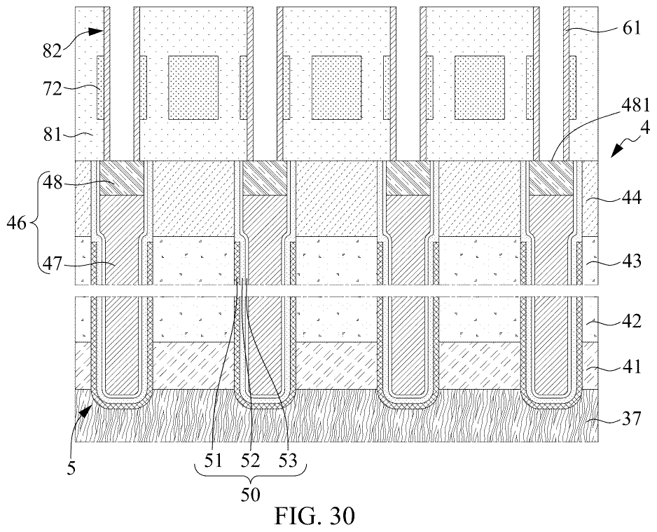

FIG. 30 illustrates a partially enlarged cross-sectional view of one or more stages of an example of a method of manufacturing a semiconductor structure in accordance with one embodiment of the present disclosure.

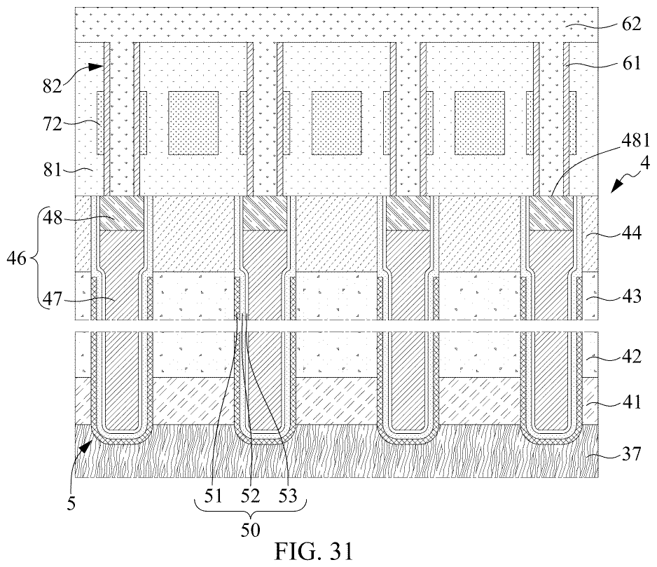

FIG. 31 illustrates a partially enlarged cross-sectional view of one or more stages of an example of a method of manufacturing a semiconductor structure in accordance with one embodiment of the present disclosure.

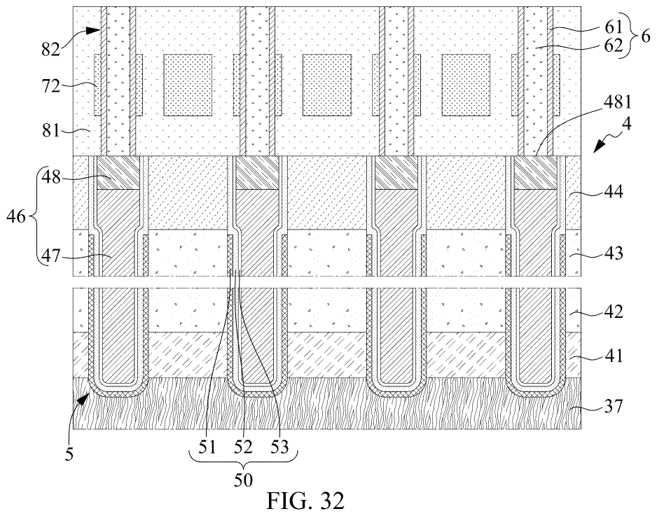

FIG. 32 illustrates a partially enlarged cross-sectional view of one or more stages of an example of a method of manufacturing a semiconductor structure in accordance with one embodiment of the present disclosure.

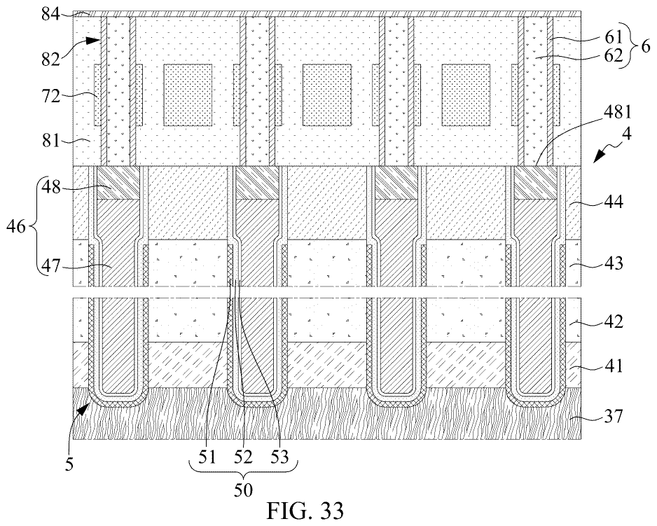

FIG. 33 illustrates a partially enlarged cross-sectional view of one or more stages of an example of a method of manufacturing a semiconductor structure in accordance with one embodiment of the present disclosure.

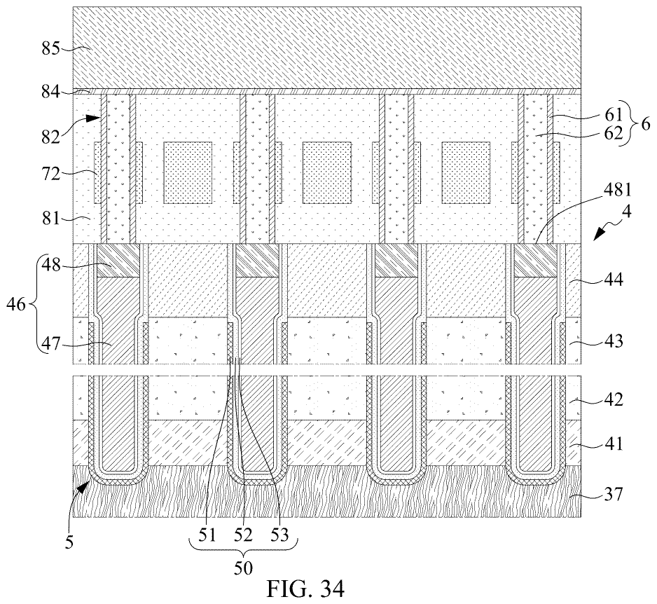

FIG. 34 illustrates a partially enlarged cross-sectional view of one or more stages of an example of a method of manufacturing a semiconductor structure in accordance with one embodiment of the present disclosure.

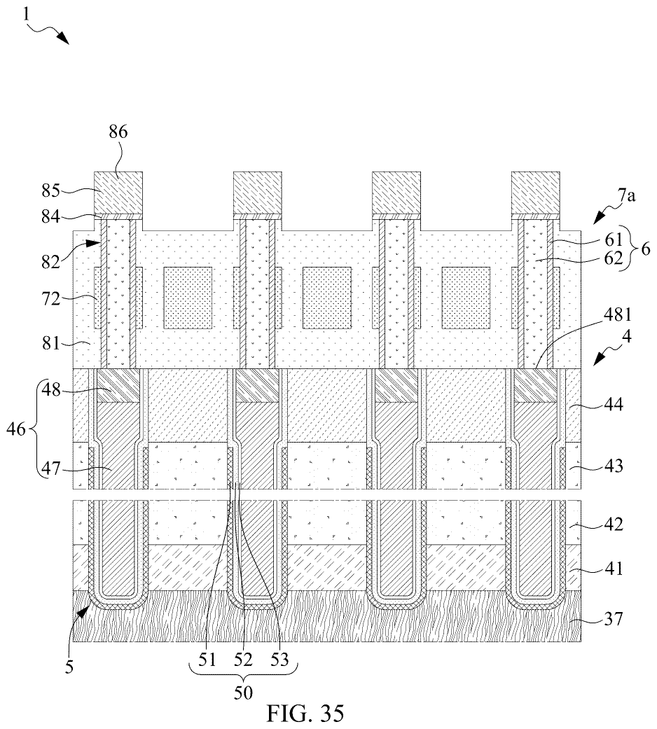

FIG. 35 illustrates a partially enlarged cross-sectional view of one or more stages of an example of a method of manufacturing a semiconductor structure in accordance with one embodiment of the present disclosure.

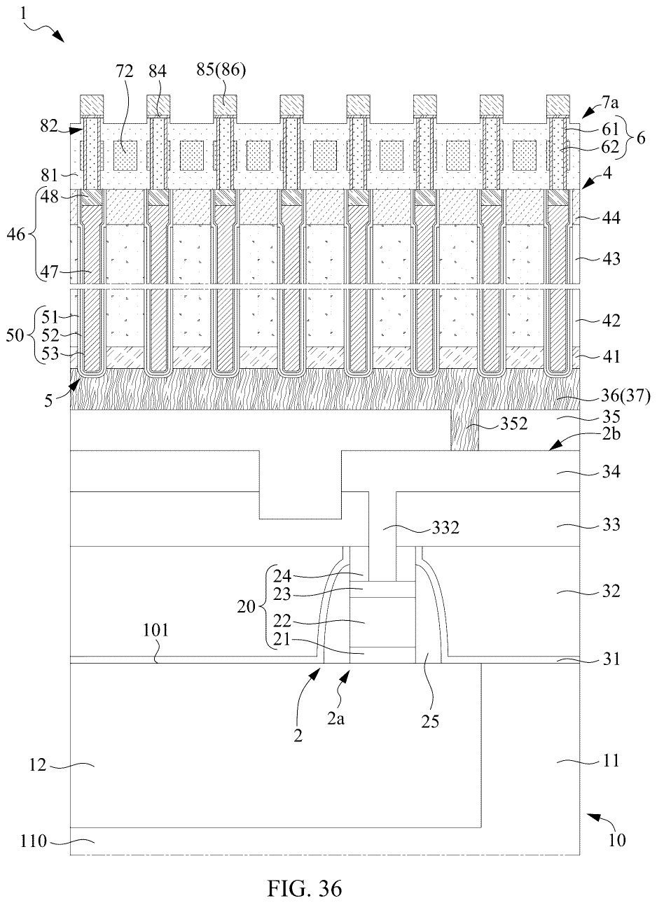

FIG. 36 illustrates a partially enlarged cross-sectional view of a semiconductor structure in accordance with one embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 illustrates, in a flowchart diagram form, a method 900 for manufacturing a semiconductor structure 1 in accordance with one embodiment of the present disclosure. FIG. 2 to FIG. 36 illustrate stages of a method for manufacturing a semiconductor structure 1 in accordance with one embodiment of the present disclosure. At least some of these figures have been simplified for a better understanding of the aspects of the present disclosure.

Referring to FIG. 2 to FIG. 8, at step S901, a patterned circuit structure 2 (including, for example, a first patterned circuit structure 2a and a second patterned circuit structure 2b) may be formed on a base structure 10 (or a substrate). Referring to FIG. 2, a base structure 10 may be provided. The base structure 10 may be a substrate, and may include a dielectric material, such as an oxide material or a nitride material. Alternatively, the base structure 10 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some other embodiments, the base structure 10 may include a semiconductor-on-insulator substrate, such as a silicon-on-insulator (SOI) substrate, a silicon germanium-on-insulator (SGOI) substrate, or a germanium-on-insulator (GOI) substrate. Depending on the IC fabrication stage, the base structure 10 may include various material layers (e.g., dielectric layers, semiconductor layers, and/or conductive layers) configured to form IC features (e.g., doped regions, isolation features, gate features, source/drain features, interconnect features, other features, or combinations thereof).

In some embodiments, the base structure 10 may include a base portion 110, a plurality of active areas 11 and a shadow trench isolation (STI) region 12. Each of the active areas 11 may be a pad protruding from the base portion 110, and may include silicon (Si) material. For example, each of the active areas 11 may be configured to form at least one drain electrode and at least one source electrode thereon. The shadow trench isolation (STI) region 12 may be disposed between the active areas 11, and may include a dielectric oxide material disposed therein. The active areas 11 may be exposed from a first surface 101 (e.g., a top surface) of the base structure 10.

Referring to FIG. 3, the first patterned circuit structure 2a may be formed or disposed on the active areas 11 exposed from the first surface 101 (e.g., the top surface) of the base structure 10. The first patterned circuit structure 2a may include a gate structure (or a gate electrode) that includes a gate oxide layer 21, a first gate conductor layer 22, a second gate conductor layer 23 and an upper layer 24. The gate oxide layer 21 may be disposed on the first surface 101 (e.g., the top surface) of the base structure 10, and may include an oxide material for electrical insulation. The first gate conductor layer 22 may be disposed on the gate oxide layer 21, and may include a polysilicon material. The second gate conductor layer 23 may be disposed on the first gate conductor layer 22, and may include a tungsten silicide (WSix) material. The upper layer 24 may be disposed on the second gate conductor layer 23, and may include a nitride material. Thus, the first patterned circuit structure 2a may include a plurality of segments 2′ separated from each other. The gate structure (or the gate electrode) of the segment 2′ of the first patterned circuit structure 2a may be a stacked structure including the gate oxide layer 21, the first gate conductor layer 22, the second gate conductor layer 23 and the upper layer 24 stacked on one another.

Then, a doping process may be conducted to form at least one drain electrode and at least one source electrode in the active area 11 and adjacent to the gate structure (or the gate electrode) so as to form a metal-oxide-semiconductor (MOS) structure 20. Thus, the first patterned circuit structure 2a may include a MOS structure 20. The MOS structure 20 may include the drain electrode, the source electrode and the gate structure (including the gate oxide layer 21, the first gate conductor layer 22, the second gate conductor layer 23 and the upper layer 24).

Referring to FIG. 4, a spacer 25 may be formed on the lateral surface of the gate structure (or the gate electrode) and on the drain electrode and the source electrode. The spacer 25 may surround the gate structure (including, e.g., the gate oxide layer 21, the first gate conductor layer 22, the second gate conductor layer 23 and the upper layer 24) or may be disposed around the gate structure. In some embodiments, the spacer 25 may include an oxide material. An upper portion of the upper layer 24 may be exposed by the spacer 25. In some embodiments, the spacer 25 may be a portion of the first patterned circuit structure 2a. In some embodiments, the first patterned circuit structure 2a may be also referred to as “a core circuit or “a periphery circuit”.

Referring to FIG. 5, a first insulation layer 31 may be formed on the first patterned circuit structure 2a and the first surface 101 (e.g., the top surface) of the base structure 10. The first insulation layer 31 may include a nitride material, and may be formed by deposition. The first insulation layer 31 may be conformal with the first patterned circuit structure 2a and the first surface 101 (e.g., the top surface) of the base structure 10. Then, a second insulation layer 32 may be formed on the first insulation layer 31. The second insulation layer 32 may include an oxide material, and may be formed by coating. The second insulation layer 32 may fill the space between the segments 2′ of the first patterned circuit structure 2a, and may have a substantially flat top surface. Then, an annealing process may be conducted to the second insulation layer 32. Then, a chemical mechanical planarization (CMP) process may be conducted to the top surface of the second insulation layer 32. Thus, a portion of an upper portion of the upper layer 24 of the first patterned circuit structure 2a may be removed. A top surface of the upper layer 24 of the first patterned circuit structure 2a may be substantially coplanar with the top surface of the second insulation layer 32. The top surface of the upper layer 24 of the first patterned circuit structure 2a may be exposed by the second insulation layer 32.

Referring to FIG. 6, a first intermediate layer 33 may be formed or disposed on the upper layer 24 of the first patterned circuit structure 2a and the second insulation layer 32. The first intermediate layer 33 may be an insulation layer (e.g., a nitride material), and may be formed by deposition. Then, a plurality of through holes 331 may be formed in the first intermediate layer 33 by etching. A first portion of the through holes 331 may extend through the first intermediate layer 33 and the upper layer 24 of the first patterned circuit structure 2a so as to expose portions of the second gate conductor layer 23 of the gate structure. A second portion of the through holes 331 may extend through the first intermediate layer 33, the second insulation layer 32 and the first insulation layer 31 so as to expose the source electrode and drain electrode.

Referring to FIG. 7, a conductive material 34 may be formed or disposed on the first intermediate layer 33 to form a conductive layer. A portion of the conductive material 34 may be formed in the through holes 331 of the first intermediate layer 33 to form a plurality of first through vias 332. Some of the first through vias 332 may extend through the first intermediate layer 33 and the upper layer 24 of the first patterned circuit structure 2a. The other first through vias 332 may extend through the first intermediate layer 33, the second insulation layer 32 and the first insulation layer 31. The conductive material 34 may include tungsten (W), copper (Cu) or titanium nitride (TiN), and may be formed by deposition.

Referring to FIG. 8, a patterning process may be conducted to the conductive material 34. Thus, portions of the conductive material 34 may be removed by etching to form a second patterned circuit structure 2b. The second patterned circuit structure 2b may include a plurality of segments 2″ separated from each other. The second patterned circuit structure 2b and the first through vias 332 may be formed integrally. In some embodiments, portions of the upper portion of the first intermediate layer 33 may be removed concurrently during the patterning process so as to form a plurality of recess portions. The recess portions may not extend through the first intermediate layer 33.

The first intermediate layer 33 may be disposed between or interposed between the second patterned circuit structure 2b and the first patterned circuit structure 2a. The second patterned circuit structure 2b may be disposed over or right above the first patterned circuit structure 2a, and may be electrically connected to the first patterned circuit structure 2a through the first through vias 332 extending through the first intermediate layer 33. The second patterned circuit structure 2b may be a single-layered structure, and may be a local interconnection layer or a redistribution layer. The pattern or layout of the second patterned circuit structure 2b may be different from the pattern or layout of the first patterned circuit structure 2a.

Referring to FIG. 9, a second intermediate layer 35 may be formed or disposed on the second patterned circuit structure 2b and the recess portions of the first intermediate layer 33. The second intermediate layer 35 may be an insulation layer (e.g., an oxide material), and may be formed by deposition. Then, a plurality of through holes 351 may be formed in the second intermediate layer 35 by etching. The through holes 351 may extend through the second intermediate layer 35 so as to expose portions of second patterned circuit structure 2b.

Referring to FIG. 10, a conductive material 36 may be formed or disposed on the second intermediate layer 35 to form a conductive layer 37. A portion of the conductive material 36 may be formed in the through holes 351 of the second intermediate layer 35 to form a plurality of second through vias 352. The second through vias 352 may extend through the second intermediate layer 35. The conductive material 36 may include tungsten (W), copper (Cu) or titanium nitride (TiN), and may be formed by deposition.

The conductive layer 37 may be an unpatterned layer without any pattern. The conductive layer 37 may be disposed right above the patterned circuit structure 2 (including the first patterned circuit structure 2a and the second patterned circuit structure 2b). Thus, the conductive layer 37 may be disposed over and may vertically overlap the patterned circuit structure 2 (including the first patterned circuit structure 2a and the second patterned circuit structure 2b). The conductive layer 37 and the second through vias 352 may be formed integrally.

The second intermediate layer 35 may be disposed between or interposed between the conductive layer 37 and the patterned circuit structure 2 (including the first patterned circuit structure 2a and the second patterned circuit structure 2b). The conductive layer 37 may be disposed over or right above the second patterned circuit structure 2b, and may be electrically connected to the second patterned circuit structure 2b through the second through vias 352 extending through the second intermediate layer 35. The conductive layer 37 may be a single-layered structure.

Referring to FIG. 11, an intermediate structure 4 may be formed or disposed on the conductive layer 37 (i.e., on the base structure 10). Thus, the intermediate structure 4 may be formed or disposed over the patterned circuit structure 2 (including the first patterned circuit structure 2a and the second patterned circuit structure 2b). The intermediate structure 4 may include a first support layer 41, a lower material layer 42, an upper material layer 43 and a second support layer 44. The first support layer 41 may be formed or disposed on the conductive layer 37 by deposition. For example, the first support layer 41 may be a dielectric layer or an insulation layer, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof.

The lower material layer 42 may be formed or disposed on the first support layer 41 by deposition. The lower material layer 42 may include a dielectric material or an insulation material, such as nitride, oxide, oxynitride amorphous silicon, polycrystalline silicon, or other suitable another. For example, the lower material layer 42 may include boron phosphorus silicate glass (BPSG) that is an oxide doped with boron and phosphorus.

The upper material layer 43 may be formed or disposed on the lower material layer 42 by deposition. The upper material layer 43 may be include a dielectric material or an insulation material, such as nitride, oxide, oxynitride amorphous silicon, polycrystalline silicon, or other suitable another. For example, the upper material layer 43 may include, but are not limited to, hafnium silicate (HfSiOₓ), hafnium oxide (HfO₂), zirconium silicate (ZrSiOₓ), zirconium oxide (ZrO₂), silicon nitride (Si₃N₄), silicon oxynitride (SiON), or silicon oxide (SiO₂), tetraethylorthosilicate (TEOS), carbon-doped silicon, etc. The material of the upper material layer 43 may be same as or different from the material of the lower material layer 42. The lower material layer 42 and the upper material layer 43 may have different etching rates with respect to an etchant. In some embodiments, the lower material layer 42 may have a faster etching rate than the upper material layer 43. Further, a thickness of the upper material layer 43 may be equal to or different from a thickness of the lower material layer 42.

The second support layer 44 may be formed or disposed on the upper material layer 43 by deposition. For example, the second support layer 44 may be a dielectric layer or an insulation layer, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof. The material of the second support layer 44 may be same as or different from the material of the first support layer 41. The thickness of the second support layer 44 may be equal to or different from the thickness of the first support layer 41.

Referring to FIG. 12 and FIG. 13, wherein FIG. 13 illustrates a partially enlarged left side view FIG. 12, at step S902, a capacitor structure 5 may be formed or disposed over the patterned circuit structure 2 (including the first patterned circuit structure 2a and the second patterned circuit structure 2b), and may be embedded in the intermediate structure 4. The capacitor structure 5 may include a plurality of capacitors 50 arranged in an array and extending through the first support layer 41, the lower material layer 42, the upper material layer 43 and the second support layer 44. The capacitors 50 are electrically connected to the conductive layer 37 and the patterned circuit structure 2 (including the first patterned circuit structure 2a and the second patterned circuit structure 2b). Thus, the capacitors 50 vertically overlap the conductive layer 37 and the patterned circuit structure 2 (including the first patterned circuit structure 2a and the second patterned circuit structure 2b). In addition, the active areas 11 and the shadow trench isolation (STI) region 12 may be disposed right under the capacitor structure 5.

Each of the capacitors 50 may be embedded in the intermediate structure 4. In some embodiments, the capacitor 50 may be a vertical ring structure and may surround a central portion 46. The central portion 46 may be in a cylinder shape, and may include a base material 47 and a conductive material 48. The base material 47 may include a conductor. The conductive material 48 may include indium tin oxide (ITO).

The capacitor 50 may include a first electrode 51 (e.g., a bottom electrode), an intermediate layer 52 and a second electrode 53 (e.g., a top electrode). It is contemplated that the number of the capacitor 50 is not limited. The second electrode 53 may be a conductive layer such as titanium nitride (TiN) layer. The second electrode 53 may be disposed on and surround the lateral surface of the central portion 46. Thus, the second electrode 53 may be interposed between the central portion 46 and the intermediate layer 52. Further, the intermediate layer 52 may be a high-k dielectric layer such as zirconium oxide (ZrO₂) layer. The intermediate layer 52 may be disposed on and surround the lateral surface of the second electrode 53. Thus, the intermediate layer 52 may be interposed between the second electrode 53 and the first electrode 51. Further, the first electrode 51 may be a conductive layer such as titanium nitride (TiN) layer. The first electrode 51 may be disposed on and surround the lateral surface of the intermediate layer 52. Thus, the first electrode 51 may be interposed between the intermediate layer 52 and the intermediate structure 4.

In some embodiments, the conductive material 48 of the central portion 46 contacts the second electrode 53. In addition, a top surface 481 of the conductive material 48 of the central portion 46, a top surface 531 of the second electrode 53, a top surface 521 of the intermediate layer 52 and a top surface 441 of the second support layer 44 may be substantially coplanar with each other.

Further, the first electrode 51 may be disposed below the conductive material 48 of the central portion 46. That is, an elevation of a top surface of the first electrode 51 may be lower than an elevation of a bottom surface of the conductive material 48 of the central portion 46 and below an elevation of a bottom surface of the second support layer 44. The capacitor 50 may extend through the first support layer 41, and extend into the conductive layer 37. Thus, the capacitor 50 may be electrically connected to the conductive layer 37. Meanwhile, a semiconductor structure 1a may be formed.

Referring to FIG. 14 to FIG. 32, at step S903, a vertical transistor 6 may be formed or disposed over the capacitor structure 5. Referring to FIG. 14, an upper structure 7 may be formed or disposed on the intermediate structure 4. The upper structure 7 may include a bottom insulation layer 71, a conductive layer 72 and a top insulation layer 73. The bottom insulation layer 71 may be disposed on the top surface of the intermediate structure 4. The bottom insulation layer 71 may include an oxide material, and may be formed by deposition. The conductive layer 72 may be disposed on the bottom insulation layer 71. The conductive layer 72 may include tungsten (W), and may be formed by deposition. In some embodiments, the conductive layer 72 may include signal lines, such as word lines. The top insulation layer 73 may be disposed on the conductive layer 72. The top insulation layer 73 may include an oxide material, and may be formed by deposition.

Referring to FIG. 15, at least one hole 74 (or channel) may be formed to extend through the upper structure 7 by, for example, dry etching. Thus, the hole 74 may extend through the bottom insulation layer 71, the conductive layer 72 and the top insulation layer 73. The hole 74 may be located right above the conductive material 48 of the central portion 46. Thus, the top surface 481 of the conductive material 48 of the central portion 46 may be exposed in the hole 74. A width of the hole 74 may be less than a width of the conductive material 48 of the central portion 46.

Referring to FIG. 16, a sacrifice material 75 may be formed on the top surface of the upper structure 7 and in the hole 74 by, for example, deposition. The sacrifice material 75 may include doped polysilicon.

Referring to FIG. 17, a first portion of the sacrifice material 75 that is disposed on the top surface of the upper structure 7 may be removed by etching. Meanwhile, a second portion of the sacrifice material 75 that is disposed in the hole 74 may remain.

Referring to FIG. 18, the top insulation layer 73 may be removed by, for example, wet etching. Meanwhile, the upper portion of the sacrifice material 75 may protrude from the conductive layer 72.

Referring to FIG. 19, a third insulation material 76 may be formed or disposed on the upper portion of the sacrifice material 75 and on the top surface of the conductive layer 72 by, for example, deposition. The third insulation material 76 may have a substantially consistent thickness of 7 nm. The third insulation material 76 may include an oxide material.

Referring to FIG. 20, a first portion of the third insulation material 76 that is disposed on the top surface of the conductive layer 72 and a second portion of the third insulation material 76 that is disposed on the top surface of the sacrifice material 75 may be removed by, for example, etching. Meanwhile, a third portion of the third insulation material 76 that is disposed on the lateral surface of the sacrifice material 75 may remain to form a spacer 77.

Referring to FIG. 21, a fourth insulation material 78 may be formed or disposed on the spacer 77, the top surface of the sacrifice material 75 and the top surface of the conductive layer 72 by, for example, deposition. The fourth insulation material 78 may include carbon (C).

Referring to FIG. 22, a fifth insulation material 79 may be formed or disposed on the fourth insulation material 78 by, for example, deposition. The fifth insulation material 79 may include nitride material. Then, at least one opening 80 may be formed to extend through the fourth insulation material 78 and the fifth insulation material 79 by, for example, dry etching.

Referring to FIG. 23, portions of the conductive layer 72 may be removed by, for example, dry etching. During the etching process, the fourth insulation material 78 and the fifth insulation material 79 may be used as a mask. The opening 80 may further extend through the conductive layer 72. Thus, the conductive layer 72 may be patterned, and may include a plurality of segments (e.g., word lines) separated from each other.

Referring to FIG. 24, portions of the bottom insulation layer 71 may be removed by, for example, dry etching. During the etching process, the fourth insulation material 78 and the fifth insulation material 79 may be used as a mask. The opening 80 may further extend into the bottom insulation layer 71 but may not extend through the bottom insulation layer 71. Thus, the bottom insulation layer 71 may be patterned, and may include a plurality of recesses.

Referring to FIG. 25, the fifth insulation material 79 and the fourth insulation material 78 may be removed by, for example, stripping.

Referring to FIG. 26, a sixth insulation material 81 may be formed or disposed on the upper portion of the sacrifice material 75 and the spacer 77, in the opening 80, and in the recesses of the bottom insulation layer 71 by, for example, deposition. The sixth insulation material 81 may include oxide material. In some embodiments, the material of the sixth insulation material 81 may be same as the material of the spacer 77 and the material of the bottom insulation layer 71.

Referring to FIG. 27, a chemical mechanical planarization (CMP) process may be conducted to the sixth insulation material 81. Thus, an upper portion of the sixth insulation material 81 and a portion of the upper portion of the sacrifice material 75 may be removed. A top surface of the sacrifice material 75 may be substantially coplanar with the top surface of the sixth insulation material 81. The top surface of the sacrifice material 75 may be exposed by the sixth insulation material 81. The thickness of the sixth insulation material 81 may be 30 nm. Meanwhile, the sixth insulation material 81 and the patterned conductive layer 72 (e.g., word lines) embedded in the sixth insulation material 81 may collectively form an upper structure 7a disposed on the intermediate structure 4.

Referring to FIG. 28, the sacrifice material 75 may be removed so as to form at least one hole 82. The hole 82 may extend through the sixth insulation material 81 and the conductive layer 72 (e.g., the word lines), and expose the conductive material 48 of the central portion 46. Thus, the upper structure 7a may define the hole 82. The hole 82 may extend through the upper structure 7a. A width of the hole 82 may be less than a width of the conductive material 48 of the central portion 46.

Referring to FIG. 29, a seventh insulation material 83 may be formed or disposed on the top surface of the sixth insulation material 81 and the top surface 481 of the conductive material 48 of the central portion 46, and in the hole 82 by, for example, deposition. The seventh insulation material 83 may have a substantially consistent thickness, and may include oxide material.

Referring to FIG. 30, the portion of the seventh insulation material 83 that is disposed on the top surface of the sixth insulation material 81 and the top surface 481 of the conductive material 48 of the central portion 46 may be removed by, for example, etching. The portion of the seventh insulation material 83 that is disposed on the sidewall of the hole 82 remains so as to become to a periphery insulation layer 61 on the sidewall of the hole 82.

Referring to FIG. 31, a main material 62 may be formed in a central hole defined by the periphery insulation layer 61 and on the top surface of the sixth insulation material 81 by, for example, deposition. The main material 62 may include a conductive material such as indium-gallium-zinc oxide (IGZO).

Referring to FIG. 32, a portion of the main material 62 that is disposed on the top surface of the sixth insulation material 81 may be removed by, for example, etching. Meanwhile, a vertical transistor 6 may be formed or disposed in the hole 82. The vertical transistor 6 may include a main material 62 and a periphery insulation layer 61. The periphery insulation layer 61 may surround the main material 62 and include an insulation material. Thus, the vertical transistor 6 may be electrically connected to the capacitor 50 through the conductive material 48 of the central portion 46. The conductive material 48 of the central portion 46 may be disposed on the base material 47 and electrically connected to the vertical transistor 6. A width of the vertical transistor 6 may be less than a width of the central portion 46. Thus, a vertical projection of the vertical transistor 6 may be within the central portion 46.

Referring to FIG. 33, an upper conductive layer 84 may be formed on the top surface of the sixth insulation material 81 and on the top surface of the vertical transistor 6 by, for example, physical vapor deposition (PVD). The upper conductive layer 84 on the top surface of the vertical transistor 6 may be electrically connected to the main material 62. The upper conductive layer 84 may include transparent conductive oxide (TCO) material, such as indium tin oxide (ITO) and zinc oxide (ZnO). A thickness of the upper conductive layer 84 may be 5 nm.

Referring to FIG. 34, a conductive material 85 may be formed or disposed on the upper conductive layer 84 by, for example, physical vapor deposition (PVD). The conductive material 85 may include tungsten (W).

Referring to FIG. 35, a removing process, for example, chemical mechanical planarization (CMP) may be conducted to the conductive material 85. Then, the conductive material 85 and the upper conductive layer 84 may be patterned by, for example, etching, so as to form a plurality of electrical pads 86 (e.g., the landing pads) disposed on the vertical transistors 6. The upper conductive layer 84 may be disposed between the electrical pad 86 and the vertical transistor 6. Alternatively, the electrical pad 86 may include the conductive material 85 and the upper conductive layer 84. Meanwhile, a semiconductor structure 1 may be formed as shown in FIG. 36.

FIG. 36 illustrates a partially enlarged cross-sectional view of a semiconductor structure 1 in accordance with one embodiment of the present disclosure. In some embodiments, the semiconductor structure 1 may be a semiconductor device that includes a circuit, such as a memory cell. In some embodiments, the memory cell may include a dynamic random access memory cell (DRAM cell).

In addition, the semiconductor structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The semiconductor structure 1 may include a base structure 10, a patterned circuit structure 2 (including, for example, a first patterned circuit structure 2a and a second patterned circuit structure 2b), an intermediate structure 4, a capacitor structure 5, at least one vertical transistor 6, an upper structure 7a and a plurality of electrical pads 86 (e.g., the landing pads).

The base structure 10 may be a substrate, and may include a dielectric material, such as an oxide material or a nitride material. Alternatively, the base structure 10 may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some other embodiments, the base structure 10 may include a semiconductor-on-insulator substrate, such as a silicon-on-insulator (SOI) substrate, a silicon germanium-on-insulator (SGOI) substrate, or a germanium-on-insulator (GOI) substrate. Depending on the IC fabrication stage, the base structure 10 may include various material layers (e.g., dielectric layers, semiconductor layers, and/or conductive layers) configured to form IC features (e.g., doped regions, isolation features, gate features, source/drain features, interconnect features, other features, or combinations thereof).

In some embodiments, the base structure 10 may include a base portion 110, a plurality of active areas 11 and a shadow trench isolation (STI) region 12. Each of the active areas 11 may be a pad protruding from the base portion 110, and may include silicon (Si) material. For example, each of the active areas 11 may be configured to form at least one drain electrode and at least one source electrode thereon. The shadow trench isolation (STI) region 12 may be disposed between the active areas 11, and may include a dielectric oxide material disposed therein. The active areas 11 may be exposed from a first surface 101 (e.g., a top surface) of the base structure 10.

The patterned circuit structure 2 (including, for example, the first patterned circuit structure 2a and the second patterned circuit structure 2b) may be disposed on the base structure 10. The first patterned circuit structure 2a may be disposed on the active areas 11 exposed from the first surface 101 (e.g., the top surface) of the base structure 10. The first patterned circuit structure 2a may include a gate structure (or a gate electrode) that includes a gate oxide layer 21, a first gate conductor layer 22, a second gate conductor layer 23 and an upper layer 24.

The gate oxide layer 21 may be disposed on the first surface 101 (e.g., the top surface) of the base structure 10, and may include an oxide material for electrical insulation. The first gate conductor layer 22 may be disposed on the gate oxide layer 21, and may include a polysilicon material. The second gate conductor layer 23 may be disposed on the first gate conductor layer 22, and may include a tungsten silicide (WSix) material. The upper layer 24 may be disposed on the second gate conductor layer 23, and may include a nitride material. Thus, the first patterned circuit structure 2a may include a plurality of segments separated from each other. The gate structure (or the gate electrode) of the segment of the first patterned circuit structure 2a may be a stacked structure including the gate oxide layer 21, the first gate conductor layer 22, the second gate conductor layer 23 and the upper layer 24 stacked on one another.

At least one drain electrode and at least one source electrode may be formed in the active area 11 and adjacent to the gate structure (or the gate electrode) so as to form a metal-oxide-semiconductor (MOS) structure 20. Thus, the first patterned circuit structure 2a may include a MOS structure 20. The MOS structure 20 may include the drain electrode, the source electrode and the gate structure (including the gate oxide layer 21, the first gate conductor layer 22, the second gate conductor layer 23 and the upper layer 24).

A spacer 25 may be disposed on the lateral surface of the gate structure (or the gate electrode) and on the drain electrode and the source electrode. The spacer 25 may surround the gate structure (including, e.g., the gate oxide layer 21, the first gate conductor layer 22, the second gate conductor layer 23 and the upper layer 24) or may be disposed around the gate structure. In some embodiments, the spacer 25 may include an oxide material. In some embodiments, the spacer 25 may be a portion of the first patterned circuit structure 2a. In some embodiments, the first patterned circuit structure 2a may be also referred to as “a core circuit or “a periphery circuit”.

A first insulation layer 31 may be disposed on the first patterned circuit structure 2a and the first surface 101 (e.g., the top surface) of the base structure 10. The first insulation layer 31 may include a nitride material. The first insulation layer 31 may be conformal with the first patterned circuit structure 2a and the first surface 101 (e.g., the top surface) of the base structure 10. In addition, a second insulation layer 32 may be disposed on the first insulation layer 31. The second insulation layer 32 may include an oxide material. The second insulation layer 32 may fill the space between the segments of the first patterned circuit structure 2a, and may have a substantially flat top surface. A top surface of the upper layer 24 of the first patterned circuit structure 2a may be substantially coplanar with the top surface of the second insulation layer 32.

A first intermediate layer 33 may be disposed on the upper layer 24 of the first patterned circuit structure 2a and the second insulation layer 32. The first intermediate layer 33 may be an insulation layer (e.g., a nitride material), and may define a plurality of through holes 331. A first portion of the through holes 331 may extend through the first intermediate layer 33 and the upper layer 24 of the first patterned circuit structure 2a so as to expose portions of the second gate conductor layer 23 of the gate structure. A second portion of the through holes 331 may extend through the first intermediate layer 33, the second insulation layer 32 and the first insulation layer 31 so as to expose the source electrode and drain electrode.

A conductive material 34 may be disposed on the first intermediate layer 33 to form a conductive layer. A portion of the conductive material 34 may be disposed in the through holes 331 of the first intermediate layer 33 to form a plurality of first through vias 332. Some of the first through vias 332 may extend through the first intermediate layer 33 and the upper layer 24 of the first patterned circuit structure 2a. The other first through vias 332 may extend through the first intermediate layer 33, the second insulation layer 32 and the first insulation layer 31. The conductive material 34 may include tungsten (W), copper (Cu) or titanium nitride (TiN), and may be formed by deposition.

The conductive material 34 may be patterned to form the second patterned circuit structure 2b. The second patterned circuit structure 2b may include a plurality of segments separated from each other. The second patterned circuit structure 2b and the first through vias 332 may be formed integrally.

The first intermediate layer 33 may be disposed between or interposed between the second patterned circuit structure 2b and the first patterned circuit structure 2a. The second patterned circuit structure 2b may be disposed over or right above the first patterned circuit structure 2a, and may be electrically connected to the first patterned circuit structure 2a through the first through vias 332 extending through the first intermediate layer 33. The second patterned circuit structure 2b may be a single-layered structure, and may be a local interconnection layer or a redistribution layer. The pattern or layout of the second patterned circuit structure 2b may be different from the pattern or layout of the first patterned circuit structure 2a.

A second intermediate layer 35 may be disposed on the second patterned circuit structure 2b. The second intermediate layer 35 may be an insulation layer (e.g., an oxide material), and may define a plurality of through holes 351. The through holes 351 may extend through the second intermediate layer 35 so as to expose portions of second patterned circuit structure 2b.

A conductive material 36 may be disposed on the second intermediate layer 35 to form a conductive layer 37. A portion of the conductive material 36 may be formed in the through holes 351 of the second intermediate layer 35 to form a plurality of second through vias 352. The second through vias 352 may extend through the second intermediate layer 35. The conductive material 36 may include tungsten (W), copper (Cu) or titanium nitride (TiN).

The conductive layer 37 may be an unpatterned layer without any pattern. The conductive layer 37 may be also referred to as “an unpatterned conductive layer”. The conductive layer 37 may be disposed right above the patterned circuit structure 2 (including the first patterned circuit structure 2a and the second patterned circuit structure 2b). Thus, the conductive layer 37 may be disposed over and may vertically overlap the patterned circuit structure 2 (including the first patterned circuit structure 2a and the second patterned circuit structure 2b). The conductive layer 37 and the second through vias 352 may be formed integrally.

The second intermediate layer 35 may be disposed between or interposed between the conductive layer 37 and the patterned circuit structure 2 (including the first patterned circuit structure 2a and the second patterned circuit structure 2b). The conductive layer 37 may be disposed over or right above the second patterned circuit structure 2b, and may be electrically connected to the second patterned circuit structure 2b through the second through vias 352 extending through the second intermediate layer 35. The conductive layer 37 may be a single-layered structure.

The intermediate structure 4 may be disposed on the conductive layer 37 (i.e., on the base structure 10). Thus, the intermediate structure 4 may be disposed over the patterned circuit structure 2 (including the first patterned circuit structure 2a and the second patterned circuit structure 2b). The intermediate structure 4 may include a first support layer 41, a lower material layer 42, an upper material layer 43 and a second support layer 44. The first support layer 41 may be disposed on the conductive layer 37. For example, the first support layer 41 may be a dielectric layer or an insulation layer, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof.

The lower material layer 42 may be disposed on the first support layer 41. The lower material layer 42 may include a dielectric material or an insulation material, such as nitride, oxide, oxynitride amorphous silicon, polycrystalline silicon, or other suitable another. For example, the lower material layer 42 may include boron phosphorus silicate glass (BPSG) that is an oxide doped with boron and phosphorus.

The upper material layer 43 may be disposed on the lower material layer 42. The upper material layer 43 may be include a dielectric material or an insulation material, such as nitride, oxide, oxynitride amorphous silicon, polycrystalline silicon, or other suitable another. For example, the upper material layer 43 may include, but are not limited to, hafnium silicate (HfSiOₓ), hafnium oxide (HfO₂), zirconium silicate (ZrSiOₓ), zirconium oxide (ZrO₂), silicon nitride (Si₃N₄), silicon oxynitride (SiON), or silicon oxide (SiO₂), tetraethylorthosilicate (TEOS), carbon-doped silicon, etc. The material of the upper material layer 43 may be same as or different from the material of the lower material layer 42.

The second support layer 44 may be disposed on the upper material layer 43. For example, the second support layer 44 may be a dielectric layer or an insulation layer, and may include silicon nitride (Si₃N₄, or SiN), silicon dioxide (SiO₂), silicon oxynitride (N₂OSi₂), silicon nitride oxide (SiON), tantalum pentoxide (Ta₂O₅), aluminum oxide (Al₂O₃), strontium bismuth tantalum oxide (SrBi₂Ta₂O₉, SBT), barium strontium titanate oxide (BaSrTiO₃, BST), or a combination thereof. The material of the second support layer 44 may be same as or different from the material of the first support layer 41.

The capacitor structure 5 may be disposed over the patterned circuit structure 2 (including the first patterned circuit structure 2a and the second patterned circuit structure 2b), and may be embedded in the intermediate structure 4. The capacitor structure 5 may include a plurality of capacitors 50 arranged in an array and extending through the first support layer 41, the lower material layer 42, the upper material layer 43 and the second support layer 44. The capacitors 50 are electrically connected to the conductive layer 37 and the patterned circuit structure 2 (including the first patterned circuit structure 2a and the second patterned circuit structure 2b). Thus, the capacitors 50 vertically overlap the conductive layer 37 and the patterned circuit structure 2 (including the first patterned circuit structure 2a and the second patterned circuit structure 2b). In addition, the active areas 11 and the shadow trench isolation (STI) region 12 may be disposed right under the capacitor structure 5.

Each of the capacitors 50 may be embedded in the intermediate structure 4. In some embodiments, the capacitor 50 may be a vertical ring structure and may surround a central portion 46. The central portion 46 may be in a cylinder shape, and may include a base material 47 and a conductive material 48. The base material 47 may include a conductor. The conductive material 48 may include indium tin oxide (ITO).

The capacitor 50 may include a first electrode 51 (e.g., a bottom electrode), an intermediate layer 52 and a second electrode 53 (e.g., a top electrode). It is contemplated that the number of the capacitor 50 is not limited. The second electrode 53 may be a conductive layer such as titanium nitride (TiN) layer. The second electrode 53 may be disposed on and surround the lateral surface of the central portion 46. Thus, the second electrode 53 may be interposed between the central portion 46 and the intermediate layer 52. Further, the intermediate layer 52 may be a high-k dielectric layer such as zirconium oxide (ZrO₂) layer. The intermediate layer 52 may be disposed on and surround the lateral surface of the second electrode 53. Thus, the intermediate layer 52 may be interposed between the second electrode 53 and the first electrode 51. Further, the first electrode 51 may be a conductive layer such as titanium nitride (TiN) layer. The first electrode 51 may be disposed on and surround the lateral surface of the intermediate layer 52. Thus, the first electrode 51 may be interposed between the intermediate layer 52 and the intermediate structure 4.

In some embodiments, the conductive material 48 of the central portion 46 contacts the second electrode 53. In addition, a top surface 481 of the conductive material 48 of the central portion 46, a top surface 531 of the second electrode 53, a top surface 521 of the intermediate layer 52 and a top surface 441 of the second support layer 44 may be substantially coplanar with each other.

Further, the first electrode 51 may be disposed below the conductive material 48 of the central portion 46. That is, an elevation of a top surface of the first electrode 51 may be lower than an elevation of a bottom surface of the conductive material 48 of the central portion 46 and below an elevation of a bottom surface of the second support layer 44. The capacitor 50 may extend through the first support layer 41, and extend into the conductive layer 37. Thus, the capacitor 50 may be electrically connected to the conductive layer 37.

The upper structure 7a may be disposed on or disposed over the intermediate structure 4. The upper structure 7a may include a sixth insulation material 81 and a patterned conductive layer 72 (e.g., word lines) embedded in the sixth insulation material 81. The conductive layer 72 may include tungsten (W). The sixth insulation material 81 may include oxide material. The upper structure 7a may define at least one hole 82 extending through the upper structure 7a. A width of the hole 82 may be less than a width of the conductive material 48 of the central portion 46.

The vertical transistor 6 may be disposed over the capacitor structure 5, and embedded in the upper structure 7a. The vertical transistor 6 may be disposed in the hole 82. The vertical transistor 6 may include a main material 62 and a periphery insulation layer 61. The main material 62 may include a conductive material such as indium-gallium-zinc oxide (IGZO). The periphery insulation layer 61 may include an insulation material such as oxide material.

The periphery insulation layer 61 may be disposed on the sidewall of the hole 82, and may surround the main material 62. The vertical transistor 6 may be electrically connected to the capacitor 50 through the conductive material 48 of the central portion 46. The conductive material 48 of the central portion 46 may be disposed on the base material 47 and electrically connected to the vertical transistor 6. A width of the vertical transistor 6 may be less than a width of the central portion 46. Thus, a vertical projection of the vertical transistor 6 may be within the central portion 46.

The electrical pads 86 (e.g., the landing pads) may be disposed on the vertical transistors 6. The electrical pads 86 (e.g., the landing pads) may include tungsten (W). An upper conductive layer 84 may be disposed between the electrical pad 86 and the vertical transistor 6. Alternatively, the electrical pad 86 may include the upper conductive layer 84. The upper conductive layer 84 on the top surface of the vertical transistor 6 may be electrically connected to the main material 62. The upper conductive layer 84 may include transparent conductive oxide (TCO) material, such as indium tin oxide (ITO) and zinc oxide (ZnO).

In the embodiment illustrated in FIG. 36, the patterned circuit structure 2 (including the first patterned circuit structure 2a and the second patterned circuit structure 2b) is disposed right under the capacitor structure 5 and the vertical transistor 6 rather than disposed on a side of the capacitor structure 5 and the vertical transistor 6. The capacitor structure 5 and the vertical transistor 6 are stacked on the patterned circuit structure 2 (including the first patterned circuit structure 2a and the second patterned circuit structure 2b). Thus, the size (e.g., the width) of the semiconductor structure 1 may be reduced.

One aspect of the present disclosure provides a semiconductor structure. The semiconductor structure includes a base structure, a patterned circuit structure, a capacitor structure and a vertical transistor. The patterned circuit structure is disposed over the base structure. The capacitor structure is disposed over the patterned circuit structure. The vertical transistor is disposed over the capacitor structure.

Another aspect of the present disclosure provides a semiconductor structure. The semiconductor structure includes a base structure, a patterned circuit structure, an intermediate structure, a capacitor structure, an upper structure and a vertical transistor. The patterned circuit structure is disposed over the base structure, and includes a metal-oxide-semiconductor (MOS) structure. The intermediate structure is disposed over the patterned circuit structure. The capacitor structure is embedded in the intermediate structure and is disposed over the patterned circuit structure. The upper structure is disposed on the intermediate structure. The vertical transistor is embedded in the upper structure.

Another aspect of the present disclosure provides a method of manufacturing a semiconductor structure. The method includes: forming a patterned circuit structure on a base structure; forming a capacitor structure over the patterned circuit structure; and forming a vertical transistor over the capacitor structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure, comprising:
a base structure;
a patterned circuit structure disposed over the base structure, and including a metal-oxide-semiconductor (MOS) structure;
an intermediate structure disposed over the patterned circuit structure;
a capacitor structure embedded in the intermediate structure and disposed over the patterned circuit structure;
an upper structure disposed on the intermediate structure; and
a vertical transistor embedded in the upper structure.

2. The semiconductor structure of claim 1, wherein the base structure includes a base portion, a plurality of active areas and a shadow trench isolation (STI) region between the plurality of active areas, wherein the plurality of active areas and the shadow trench isolation (STI) region are disposed right under the capacitor structure.

3. The semiconductor structure of claim 1, further comprising a redistribution layer disposed over and electrically connected to the patterned circuit structure.

4. The semiconductor structure of claim 1, further comprising an unpatterned conductive layer disposed over and electrically connected to the patterned circuit structure.

5. The semiconductor structure of claim 4, wherein the capacitor structure includes a plurality of capacitors electrically connected to the unpatterned conductive layer, wherein the plurality of capacitors vertically overlap the unpatterned conductive layer.

6. The semiconductor structure of claim 1, further comprising an electrical pad disposed on the vertical transistor.

7. The semiconductor structure of claim 1, wherein the capacitor structure includes at least one capacitor, the capacitor is a ring structure and surrounds a central portion, and the central portion includes a base material and a conductive material disposed on the base material and electrically connected to the vertical transistor.

8. The semiconductor structure of claim 7, wherein the capacitor includes a first electrode, an intermediate layer and a second electrode, the second electrode is disposed on the central portion, the intermediate layer is disposed on the second electrode, and the first electrode is disposed on the intermediate layer.

9. The semiconductor structure of claim 1, wherein the vertical transistor includes a main material and a periphery insulation layer, the main material includes indium-gallium-zinc oxide (IGZO), the periphery insulation layer surrounds the main material and includes an insulation material.
